(19) United States
(12) Patent Application Publication
(10) Pub. No.: US 2026/0206634 A1
(43) Pub. Date: Jul. 16, 2026

(54) POWER SEMICONDUCTOR PACKAGE HAVING STACKED FET DIES AND METHOD FOR FABRICATING THE SAME

(71) Applicant: Infineon Technologies Austria AG, Villach (AT)

(72) Inventors: Markus Dinkel, Unterhaching (DE); Katrin Unterhofer, München (DE); Timo Bohnenberger, Neutraubling (DE)

(21) Appl. No.: 19/444,780

(22) Filed: Jan. 9, 2026

(30) Foreign Application Priority Data
Jan. 10, 2025 (DE) 102025100764.0

(51) Int. Cl. H10W 72/60; H10W 72/00; H10W 74/10; H10W 90/00; H10W 90/28

(52) U.S. Cl. CPC H10W 72/631; H10W 72/076; H10W 74/111; H10W 90/28; H10W 90/732

(57) ABSTRACT

A power semiconductor package includes: a first FET die arranged on a power electronic substrate such that a first side of the die faces away from the substrate and a second side of the die faces a first side of the substrate; a second FET die arranged on top of the first side of the first FET die such that a second side of the second die faces the first die; a first conductive layer electrically connecting the dies to each other; an encapsulation body encapsulating the dies; a metal clip having a first portion arranged over a first side of the second die and electrically connected to a first power electrode on the first side of the second die, and a second portion arranged laterally next to the dies; and a connector electrically connecting a control electrode on the first side of the first die to the metal clip.

### TECHNICAL FIELD

The present disclosure relates to a power semiconductor package, in particular a power semiconductor package comprising a first and a second field effect transistor die stacked on top of each other, as well as to a method for fabricating such a power semiconductor package.

### BACKGROUND

Power semiconductor packages may be configured to operate with strong electrical currents, e.g. currents of up to 500A or even more, and/or high electrical voltages, e.g. voltages of up to 1200V or even more. A power semiconductor package may, for example, be a discrete power device configured to block high voltages and and/or to conduct high currents between two load electrodes that are provided by external contacts of the power semiconductor package. Such devices may be configured for use in many different automotive, industrial and household applications. One particular application of such devices is the main inverter of an electric engine. The electrical performance characteristics of such a device may depend on the size of the power transistor chips or dies implemented in the device. However, larger dies also increase the overall costs of such power semiconductor packages and it may therefore be desirable to reduce the costs at a given performance level or die footprint. Improved power semiconductor packages as well as improved methods for fabricating power semiconductor packages may help with solving these and other problems.

### SUMMARY

Various aspects pertain to a power semiconductor package, comprising: a power electronic substrate comprising a first side and an opposite second side; a first FET die, comprising a first side and an opposite second side, the first FET die arranged on the power electronic substrate such that the first side of the first FET die faces away from the power electronic substrate and such that the second side of the first FET die faces the first side of the power electronic substrate; a second FET die comprising a first side and an opposite second side, the second FET die arranged on top of the first side of the first FET die such that the second side of the second FET die faces the first FET die; a first conductive layer arranged between the first and second FET dies and electrically connecting the first and second FET dies to each other; an encapsulation body encapsulating the first and second FET dies; a first metal clip comprising a first portion and a second portion, wherein the first portion is arranged over the first side of the second FET die and is electrically connected to a first power electrode on the first side of the second FET die and wherein the second portion is arranged laterally next to the first and second FET dies; and a first connector electrically connecting a control electrode on the first side of the first FET die to the first metal clip.

Various aspects pertain to a method for fabricating a power semiconductor package, the method comprising: providing a power electronic substrate comprising a first side and an opposite second side; arranging a first junction field-effect transistor die, first FET die, comprising a first side and an opposite second side on the power electronic substrate such that the first side of the first FET die faces away from the power electronic substrate and such that the second side of the first FET die faces the first side of the power electronic substrate; arranging a second FET die comprising a first side and an opposite second side on top of the first side of the first FET die such that the second side of the second FET die faces the first FET die; arranging a first conductive layer between the first and second FET dies and thereby electrically connecting the first and second FET dies to each other; encapsulating with an encapsulation body the first and second FET dies; providing a first metal clip comprising a first portion and a second portion; arranging the first portion of the first metal clip over the first side of the second FET die and electrically connecting the first portion to a first power electrode on the first side of the second FET die and arranging the second portion laterally next to the first and second FET dies; and electrically connecting a control electrode on the first side of the first FET die to the first metal clip using a first connector.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A and 1B illustrate a plan view and a sectional view, respectively, of an exemplary power semiconductor package comprising a first and a second FET die stacked on top of each other and electrically connected to each other.

FIG. 2 illustrates an exemplary cascode circuit which may be realized using the semiconductor package of FIGS. 1A and 1B.

FIG. 3 illustrates a plan view of a further exemplary power semiconductor package which comprises first to fourth FET dies, wherein the first and third FET dies and the second and fourth FET dies, respectively, are connected in parallel.

FIG. 4 illustrates a plan view of a further exemplary semiconductor package which is similar to the power semiconductor package of FIG. 3 but wherein control electrodes of the first and third FET dies are connected to a metal clip in a different manner than in the power semiconductor package of FIG. 3.

FIG. 5 illustrates a plan view of a further exemplary semiconductor package, wherein the stacks of FET dies are arranged in a different manner than in the power semiconductor package of FIG. 3.

FIG. 6 illustrates a sectional view of a further exemplary power semiconductor package, wherein a metal clip is coupled to a substrate part and wherein the substrate part is exposed from an encapsulation body to provide an external contact of the power semiconductor package.

FIG. 7 illustrates a plan view of a further exemplary power semiconductor package, wherein connectors connecting control electrodes of the first and third FET dies to the metal clip are integral parts of the metal clip itself.

FIG. 8 is a flow chart of an exemplary method for fabricating a power semiconductor package.

### DETAILED DESCRIPTION

In the following detailed description, known structures and elements are shown in schematic form in order to facilitate describing one or more aspects of the disclosure. In this regard, directional terminology, such as "top", "bottom", "left", "right", "upper", "lower" etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such a feature or aspect may be combined with one or more other features or aspects of the other implementations as may be desired and advantageous for any given or particular application, unless specifically noted otherwise or unless technically restricted. Furthermore, to the extent that the terms "include", "have", "with" or other variants thereof are used in either the detailed description or the claims, such terms are intended to be inclusive in a manner similar to the term "comprise". The terms "coupled" and "connected", along with derivatives thereof may be used. It should be understood that these terms may be used to indicate that two elements cooperate or interact with each other regardless of whether they are in direct physical or electrical contact, or they are not in direct contact with each other; intervening elements or layers may be provided between the "bonded", "attached", or "connected" elements. However, it is also possible that the "bonded", "attached", or "connected" elements are in direct contact with each other. Also, the term "exemplary" is merely meant as an example, rather than the best or optimal.

The semiconductor dies may have contact pads (or electrodes) which allow electrical contact to be made with the integrated circuits included in the semiconductor dies. The electrodes may be arranged at both main faces of the semiconductor dies. They may include one or more electrode metal layers which are applied to the semiconductor material of the semiconductor dies. The electrode metal layers may be manufactured with any desired geometric shape and any desired material composition. For example, they may comprise or be made of a material selected of the group of Cu, Ni, NiSn, Au, Ag, Pt, Pd, an alloy of one or more of these metals, an electrically conducting organic material, or an electrically conducting semiconductor material.

In several examples layers or layer stacks are applied to one another or materials are applied or deposited onto layers. It should be appreciated that any such terms as "applied" or "deposited" are meant to cover literally all kinds and techniques of applying layers onto each other. In particular, they are meant to cover techniques in which layers are applied at once as a whole like, for example, laminating techniques as well as techniques in which layers are deposited in a sequential manner like, for example, sputtering, plating, molding, CVD, etc.

An efficient power semiconductor package as well as an efficient method for fabricating a power semiconductor package may, for example, reduce material consumption, ohmic losses, chemical waste, etc. and may thus enable energy and/or resource savings. Improved power semiconductor packages as well as improved methods for fabricating a power semiconductor package, as specified in this description, may thus at least indirectly contribute to green technology solutions, i.e. climate-friendly solutions providing a mitigation of energy and/or resource use.

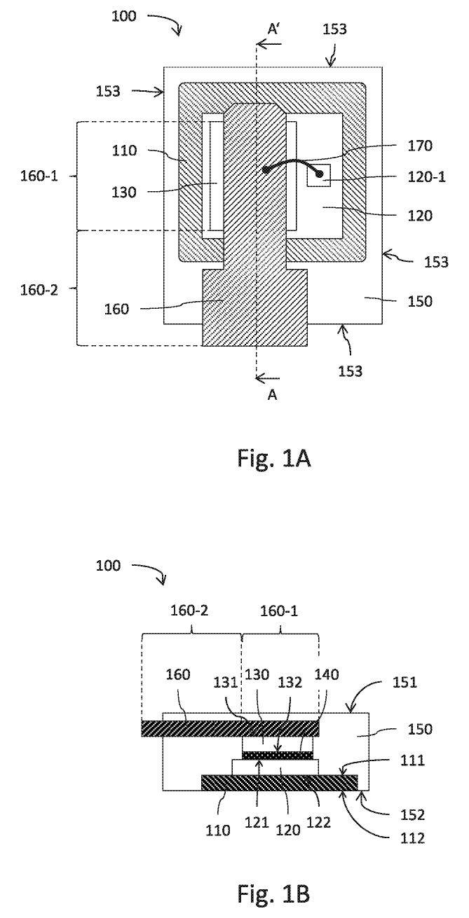

FIG. 1A shows a plan view of a power semiconductor package 100 and FIG. 1B shows a sectional view of the power semiconductor package 100 along the line A-A' in FIG. 1A. The power semiconductor package 100 comprises a power electronic substrate 110, a first field-effect transistor (FET) die 120, a second FET die 130, a first conductive layer 140, an encapsulation body 150, a first metal clip 160 and a first connector 170.

The power semiconductor package 100 may be configured as a discrete power device. A discrete power device refers to a single packaged device that is configured to block high voltages and and/or to conduct high currents as between two load electrodes. For example, the power semiconductor package 100 may be configured to operate with voltages of 100V or more, or 250V or more, or 600V or more, or 1.2kV or more. The power semiconductor package 100 may, for example, be configured to conduct currents of 10A or more, or 50A or more, or 100A or more, or 500A or more.

The power semiconductor package 100 may be configured for use in any suitable application, for example automotive applications, industrial applications or household applications. According to a specific example, the power semiconductor package 100 may be part of a main inverter of an electric engine, for example an electric engine of an electric vehicle. For example, a plurality of power semiconductor packages 100 may be electrically connected in three half bridges to provide three-phase power for the electric engine.

The power electronic substrate 110 comprises a first side 111 and an opposite second side 112. The power electronic substrate 110 may be any suitable type of substrate, for example a substrate of the type direct bonded copper (DBC), direct bonded aluminum (DBA), active metal braze (AMB), insulated metal substrate (IMS), leadframe, etc. In the example shown in FIGS. 1A and 1B, the power electronic substrate 110 comprises a single pad, wherein the first and second FET dies 120, 130 are arranged over the single pad. However, it is also possible that the power electronic substrate 110 comprises a plurality of pads. For example, the first and second FET dies 120, 130 may be arranged over one of the pads and one or more further pads may be configured as external power contacts of the power semiconductor package 100.

The first FET die 120 comprises a first side 121 and an opposite second side 122. Furthermore, the first FET die 120 is arranged on the power electronic substrate 110 such that the first side 121 of the first FET die 120 faces away from the power electronic substrate 110 and such that the second side 122 of the first FET die 120 faces the first side 111 of the power electronic substrate 110.

The first FET die 120 may have any suitable dimensions. The first FET die 120 may comprise or consist of any suitable semiconductor material. For example, the first FET die 120 may comprise or consist of Si, SiC or GaN as active semiconductor material. The first FET die 120 may comprise a first power electrode arranged on the first side 121 and a second power electrode arranged on the second side 122 (not shown in FIGS. 1A and 1B). The first power electrode may, for example, be a drain electrode or an emitter electrode and the second power electrode may be a source electrode or a collector electrode. According to another example, the first power electrode may be a source electrode or a collector electrode and the second power electrode may be a drain electrode or an emitter electrode.

Furthermore, the first FET die 120 comprises a control electrode 120-1, e.g. a gate electrode, arranged on the first side 121. The control electrode 120-1 is electrically connected to the first metal clip 160 via the first connector 170. In the example shown in FIG. 1A, the first connector 170 is a bond wire. However, it is also possible that the first connector 170 is a contact clip or a ribbon or a part (a finger) of the first metal clip 160 itself.

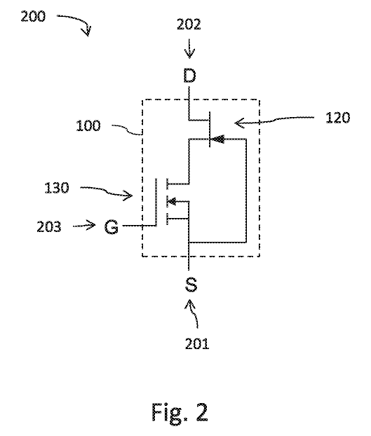

The second FET die 130 comprises a first side 131 and an opposite second side 132. Furthermore, the second FET die 130 is arranged on top of the first side 121 of the first FET die 120 such that the second side 132 of the second FET die 130 faces the first FET die 120. The second FET die 130 may, for example, comprise or consist of any of the semiconductor materials mentioned above with respect to the first FET die 120. According to a particular example, the first FET die 120 is a wide-bandgap semiconductor material, in particular but not limited to a SiC or GaN die and the second FET die 130 is a Si die. In particular, the first FET die 120 may be a depletion mode FET and the second FET die 130 may be an enhancement mode MOSEFT. The first and second FET dies 120, 130 may be connected in a cascode configuration as explained with respect to FIG. 2.

The second FET die 130 may comprise a first power electrode, a second power electrode and a control electrode in the same manner as explained above with respect to the first FET die 120. In particular, the second power electrode on the second side 122 of the first FET die 120 may be electrically connected to the power electronic substrate 110, the first power electrode on the first side 121 of the first FET die 120 may be electrically connected to the second power electrode of the second FET die 130 and the first power electrode of the second FET die 130 may be electrically connected to the first metal clip 160.

The first conductive layer 140 is arranged between the first and second FET dies 120, 130, in particular between the first side 121 of the first FET die 120 and the second side 132 of the second FET die 130. Furthermore, the first conductive layer 140 electrically connects the first and second FET dies 120, 130 to each other.

The first conductive layer 140 may comprise or consist of any suitable electrically conductive material. For example, the first conductive layer 140 may comprise or consist of a solder layer, a sintered layer or a layer of conductive glue. According to an example, the power semiconductor package 100 may comprise one or more further conductive layers. For example, there may be a further conductive layer arranged between the first FET die 120 and the power electronic substrate 110 and/or a further conductive layer arranged between the second FET die 130 and the first metal clip 160. The one or more further conductive layers may comprise or consist of the same material as the first conductive layer 140.

As shown in the example of FIGS. 1A and 1B, the second FET die 130 may have a smaller footprint than the first FET die 120 as viewed from above the first side 131 of the second FET die 130. The first conductive layer 140 may completely or almost completely cover the second side 132 (in particular the second power electrode arranged on the second side 132) of the second FET die 130.

The encapsulation body 150 encapsulates the first and second FET dies 120, 130. The encapsulation body 150 may also at least partially cover the power electronic substrate 110 and the first metal clip 160. As shown in FIG. 1B, the second side 112 of the power electronic substrate 110 may be at least partially exposed from the encapsulation body 150, for example in order to couple the second side 112 to a heatsink.

According to an example, the encapsulation body 150 comprises or consists of a molded body. Such a molded body may be fabricated using any suitable molding technique, for example compression molding, injection molding or transfer molding. According to another example, the encapsulation body 150 comprises or consists of a plastic frame enclosing an interior volume, wherein the first and second FET dies 120, 130 are arranged inside the interior volume and wherein the interior volume is at least partially filled with a potting material.

The encapsulation body 150 may have a first side 151, an opposite second side 152 and lateral sides 153 connecting the first and second sides 151, 152. The power semiconductor package 100 may have any suitable dimensions and any suitable shape. For example, the power semiconductor package 100 may have an essentially rectangular or quadratic shape as viewed from above the first side 151 of the encapsulation body 150. A rectangular shaped power semiconductor package 100 may, for example, have a longer side in the range of about 30mm to about 50mm, e.g. about 43mm and a shorter side in the range of about 10mm to about 20mm, e.g. about 15mm.

The first metal clip 160 comprises a first portion 160-1 and a second portion 160-2, wherein the first portion 160-1 is arranged over the first side 131 of the second FET die 130 and wherein the second portion 160-2 is arranged laterally next to the first and second FET dies 120, 130. Furthermore, the first portion 160-1 is electrically connected to the first power electrode on the first side 131 of the second FET die 130.

As shown in FIGS. 1A and 1B, the first and second portions 160-1 and 160-2 may be portions of a monolithic unit, i.e. the first metal clip 160. The first metal clip 160 may comprise or consist of any suitable metal or metal alloy and may, for example, comprise or consist of Al or Cu. The first metal clip 160 may, for example, be deposited over the second FET die 130 as part of a clip frame and fabricating the power semiconductor package 100 may comprise singulating the first metal clip 160 from the clip frame.

According to the example shown in FIGS. 1A and 1B, the second portion 160-2 of the first metal clip is at least partially exposed from the encapsulation body 150 (in particular, from one of the lateral sides 153 of the encapsulation body 150) in order to provide an external contact of the power semiconductor package 100. However, it is also possible that the second portion 160-2 is coupled to a part of the power electronic substrate 110 and this substrate part is exposed from the encapsulation body 150 and provides the external contact.

FIG. 2 shows a cascode circuit 200 which may be realized in the power semiconductor package 100 using the first and second FET dies 120, 130. As mentioned above, the first FET die 120 may be a depletion mode FET die and the second FET die 130 may be an enhancement mode FET die, in particular a MOSFET die, of the cascode circuit 200. The gate of the first FET die 120 may be connected to the source of the second FET die 130, in particular via the first connector 170, compare FIG. 1A.

The cascode circuit 200 may comprise a source contact 201, a drain contact 202 and a gate contact 203 which may be exposed from the encapsulation body 150 of the power semiconductor package 100.

High power applications generally have higher electrical performance requirements, e.g. concerning maximum current, maximum voltage, etc., than low power applications. Such requirements may make it necessary to increase the size of the power transistor dies in devices rated for high power applications which in turn may increase the cost of such devices. A power semiconductor package 100 comprising the cascode circuit 200 may provide excellent electrical properties while simultaneously requiring comparatively little die area. In particular, the product R_{DSon}*A, wherein R_{DSon} is the resistance between drain and source when the transistor is on and A is the die area, may be better, e.g. 30% or even 40% better, when using the cascode circuit 200 in the power semiconductor package 100 than when using enhancement mode transistor dies only.

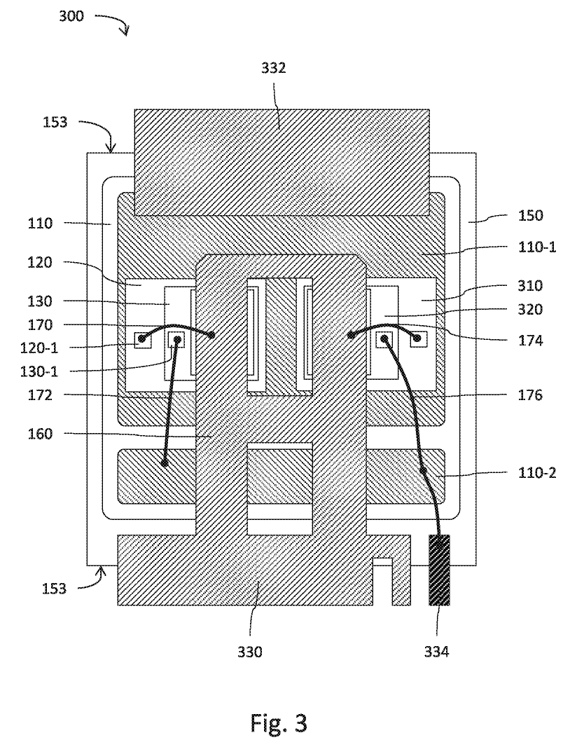

FIG. 3 shows a plan view of a further power semiconductor package 300 which may be similar or identical to the power semiconductor package 100, except for the differences described in the following.

The power semiconductor package 300 comprises all components described with respect to the power semiconductor package 100 and the power semiconductor package 300 additionally comprises a third FET die 310 and a fourth FET die 320.

Similar to the first FET die 120, the third FET die 310 comprises a first side and an opposite second side, wherein the third FET die 310 is arranged on the power electronic substrate 110 such that the first side of the third FET die 310 faces away from the power electronic substrate 110 and such that the second side of the third FET die 310 faces the first side 111 of the power electronic substrate 110. Furthermore, the third FET die 310 is arranged on the power electronic substrate 110 laterally next to the first FET die 120.

Similar to the second FET die 130, the fourth FET die 320 comprises a first side and an opposite second side, wherein the fourth FET die 320 is arranged on top of the first side of the third FET die 310 such that the second side of the fourth FET die 320 faces the third FET die 310. Furthermore, a second conductive layer is arranged between the third and fourth FET dies 310, 320 and electrically connects the third and fourth FET dies 310, 320 to each other in a similar manner as the first conductive layer 140 connects the first and second FET dies 120, 130.

The first and third FET dies 120, 310 are connected in parallel by the power electronic substrate 110 and the second and fourth FET dies 130, 320 are connected in parallel by the first metal clip 160. According to an example, both the first and third FET dies 120, 310 are depletion mode FET dies and the second and fourth FET dies 130, 320 are enhancement mode FET dies of the cascode circuit 200.

According to an example, the power semiconductor package 300 may comprise additional FET dies connected in parallel with the first FET die 120 and the second FET die 130, respectively in order to further improve the electrical characteristics of the power semiconductor package 300.

The third FET die 310 may be the same type of die as the first FET die 120 and the fourth FET die 320 may be the same type of die as the second FET die 130. Furthermore, the second conductive layer may have the same material and the same thickness as the first conductive layer.

According to an example, the power electronic substrate 110 of the power semiconductor package 300 comprises a first conductive pad 110-1 and a second conductive pad 110-2 which are separated from each other by dielectric material of the power electronic substrate 110 and/or the encapsulation body 150. The first to fourth FET dies 120-120 are arranged over the first conductive pad 110-1 and a control electrode 130-1 on the first side 131 of the second FET die 130 is electrically connected to the second conductive pad 110-2 via a second connector 172. Similar to the first FET die 120, a control electrode of the third FET die 310 may be connected to the first metal clip 160 via a third connector 174 and similar to the second FET die 130, a control electrode of the fourth FET die 320 may be connected to the second conductive pad 110-2 via a fourth connector 176. The second, third and fourth connectors 172-176 may be the same type of connector as the first connector 170.

The first metal clip 160 of the power semiconductor package 300 spans the second conductive pad 110-2. This in particular means that the first metal clip 160 is not in physical contact with the second conductive pad 110-2 and there is no direct electrical connection between the first metal clip 160 and the second conductive pad 110-2 without intermediate transistors.

The power semiconductor package 300 may comprise a first external contact 330, a second external contact 332 and a third external contact 334 exposed from the encapsulation body 150. As shown in the specific example of FIG. 3, the first and third external contacts 330, 334 may be exposed from a first one of the lateral sides 153 of the encapsulation body 150 and the second external contact 332 may be exposed from an opposite second one of the lateral sides 153. The first and second external contacts 330, 332 may be power contacts of the power semiconductor package 300 and the third external contact 334 may be a control contact, in particular a gate contact of the power semiconductor package 300. For example, the first external contact 330 may be a source contact and the second external contact may be a drain contact of the power semiconductor package 300 (for example, of the cascode circuit 200). According to another example, the source and drain contacts are reversed.

The second external contact 332 may be connected to power electrodes on the second sides of the first and third FET dies 120, 310 via the first conductive pad 110-1. The second external contact 332 may comprise or consist of a second metal clip. The second metal clip may comprise a first portion and a second portion, wherein the first portion is arranged over the first side 111 of the power electronic substrate 110 and wherein the second portion is exposed from the encapsulation body 150.

As shown in FIG. 3, the third external contact 334 may be connected to the gate electrodes of the second and fourth FET dies 130, 320. In particular, the control electrode 130-1 of the second FET die 130 may be connected to the third external contact 334 via the second conductive pad 110-2. The third contact 334 may, for example, comprise or consist of a third metal clip which may, for example, be part of the same clip frame as the first metal clip 160.

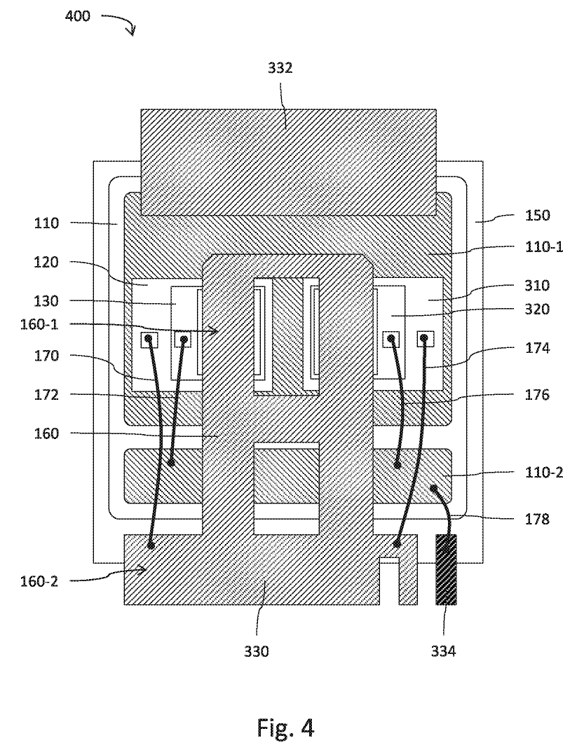

FIG. 4 shows a plan view of a further power semiconductor package 400 which may be similar or identical to the power semiconductor package 300, except for the differences described in the following.

In particular, in the power semiconductor package 300 the first and third connectors 170, 174 are attached to the first portion 160-1 of the first metal clip 160. In the power semiconductor package 400 on the other hand the first and third connectors 170, 174 are attached to the second portion 160-2 of the first metal clip. As shown in FIG. 4, the power semiconductor package 400 may comprise a fifth connector 178 connecting the second conductive pad 110-2 to the third external contact 334.

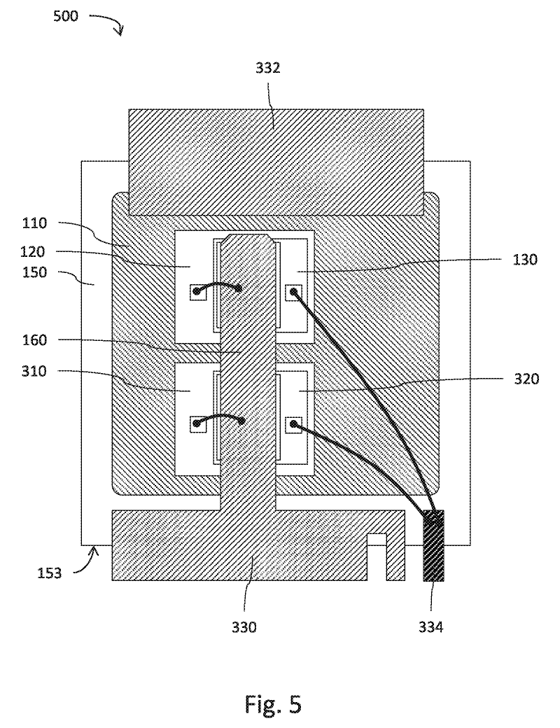

FIG. 5 shows a plan view of a further power semiconductor package 500 which may be similar or identical to the power semiconductor package 300 or 400, except for the differences described in the following.

In particular, in the power semiconductor package 500 the stacks comprising the first and second FET dies 120, 130 and the third and fourth FET dies 310, 320, respectively, are arranged along a direction which runs perpendicular to the lateral side 153 from which the first external contact 330 is exposed from. In the power semiconductor packages 300 and 400 on the other hand, the stacks of FET dies are arranged along a direction which runs parallel to the lateral side 153 from which the first external contact 330 is exposed from. Furthermore, the power electronic substrate 110 of the power semiconductor package 500 does not necessarily comprise the second conductive pad 110-2. The particular arrangement of FET die stacks of the power semiconductor package 500 may make it comparatively simple to attach the second and fourth connectors 172, 176 directly to the third external contact 334, without the need to use a second conductive pad for redistribution purposes.

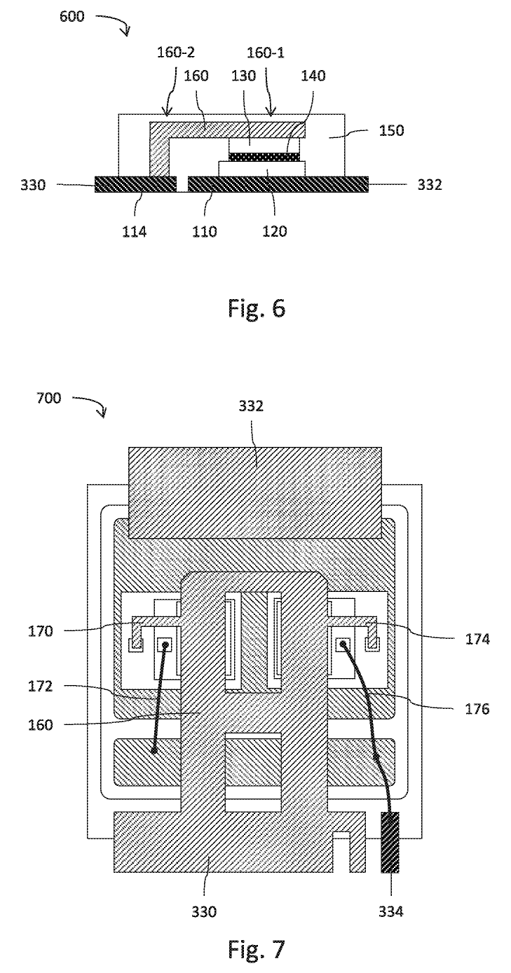

FIG. 6 shows a sectional view of a further power semiconductor package 600 which may be similar or identical to any of the power semiconductor packages 100 to 500, except for the differences described in the following.

In particular, in the power semiconductor package 600 the second portion 160-2 of the first metal clip 160 is not exposed from the encapsulation body 150 and does not form an external contact of the power semiconductor package 600. Instead, the second portion 160-2 is coupled to a substrate part 114 which may be a part of the power electronic substrate 110. The substrate part 114 is exposed from the encapsulation body 150 and provides the first external contact 330.

FIG. 7 shows a plan view of a further power semiconductor package 700 which may be similar or identical to any of the power semiconductor packages 100 to 600, except for the differences described in the following.

In particular, in the power semiconductor package 700 the first and third connectors 170, 174 connecting the control electrodes of the first and third FET dies 120, 310 to the first metal clip 160 are integral parts, e.g. fingers, of the first metal clip 160. In other words, the first and third connectors 170, 174 form a third portion and a fourth portion, respectively, of the first metal clip 160, wherein the first to fourth portions are portions of a monolithic unit.

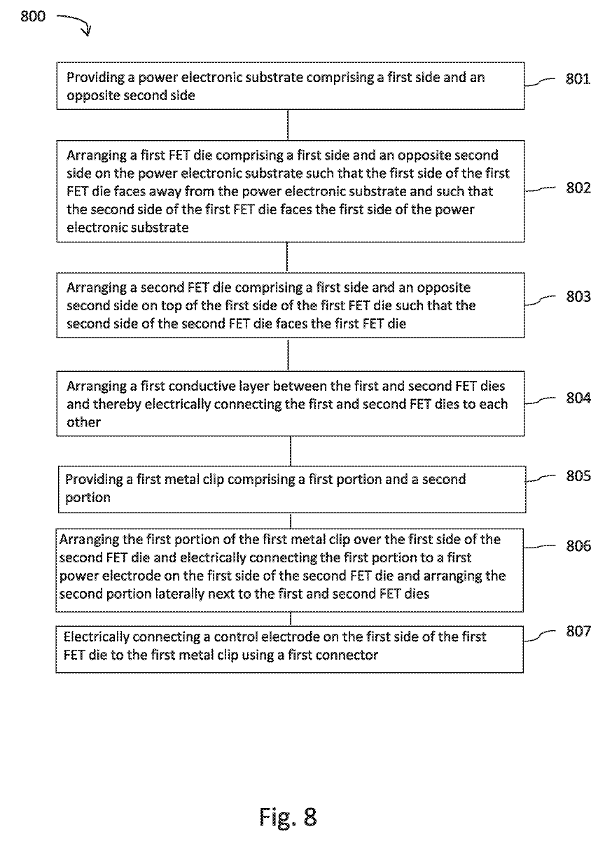

FIG. 8 is a flow chart of an exemplary method 800 for fabricating a power semiconductor package. The method 800 may, for example, be used to fabricate any of the power semiconductor packages 100 to 700.

The method 800 comprises at 801 a process of providing a power electronic substrate comprising a first side and an opposite second side, at 802 a process of arranging a first FET die comprising a first side and an opposite second side on the power electronic substrate such that the first side of the first FET die faces away from the power electronic substrate and such that the second side of the first FET die faces the first side of the power electronic substrate, at 803 a process of arranging a second FET die comprising a first side and an opposite second side on top of the first side of the first FET die such that the second side of the second FET die faces the first FET die, at 804 a process of arranging a first conductive layer between the first and second FET dies and thereby electrically connecting the first and second FET dies to each other, at 805 ,a process of providing a first metal clip comprising a first portion and a second portion, at 806 a process of arranging the first portion of the first metal clip over the first side of the second FET die and electrically connecting the first portion to a first power electrode on the first side of the second FET die and arranging the second portion laterally next to the first and second FET dies, and at 807 a process of electrically connecting a control electrode on the first side of the first FET die to the first metal clip using a first connector. The process may further comprise the step of encapsulating with an encapsulation body the first and second FET dies.

According to an example, the method 800 comprises a process of electrically connecting the first and second FET dies such that the first and second FET dies form a cascode circuit. According to an example, connecting the first portion of the first metal clip to the first power electrode on the first side of the second FET die comprises soldering or sintering the first portion to the first power electrode. According to an example, the process 805 of encapsulating the first and second FET dies comprises molding over the first and second FET dies, the first metal clip, the first conductive layer, the first connector and the first side of the power electronic substrate.

In the following, the power semiconductor package and the method for fabricating a power semiconductor package are further explained using specific examples.

Example 1 is a power semiconductor package, comprising: a power electronic substrate comprising a first side and an opposite second side; a first FET die, comprising a first side and an opposite second side, the first FET die arranged on the power electronic substrate such that the first side of the first FET die faces away from the power electronic substrate and such that the second side of the first FET die faces the first side of the power electronic substrate; a second FET die comprising a first side and an opposite second side, the second FET die arranged on top of the first side of the first FET die such that the second side of the second FET die faces the first FET die; a first conductive layer arranged between the first and second FET dies and electrically connecting the first and second FET dies to each other; an encapsulation body encapsulating the first and second FET dies; a first metal clip comprising a first portion and a second portion, wherein the first portion is arranged over the first side of the second FET die and is electrically connected to a first power electrode on the first side of the second FET die and wherein the second portion is arranged laterally next to the first and second FET dies; and a first connector electrically connecting a control electrode on the first side of the first FET die to the first metal clip.

Example 2 is the power semiconductor package of example 1, wherein the first FET is a depletion mode junction FET, and/or wherein the second FET is an enhancement mode FET, in particular a Metal-Oxide-Semiconductor Field-Effect Transistor.

Example 3 is the power semiconductor package of example 1 or 2, wherein the first FET die comprises or consists of a wide-bandgap semiconductor material, in particular SiC or GaN, and the second FET die comprises or consists of Si.

Example 4 is the power semiconductor package of one of the preceding examples, wherein the second FET die has a smaller footprint than the first FET die as viewed from above the first side of the second FET die.

Example 5 is the power semiconductor package of one of the preceding examples, further comprising: a third FET die comprising a first side and an opposite second side, the third FET die arranged on the power electronic substrate laterally next to the first FET die such that the first side of the third FET die faces away from the power electronic substrate and such that the second side of the third FET die faces the first side of the power electronic substrate; a fourth FET die comprising a first side and an opposite second side, the fourth FET die arranged on top of the first side of the third FET die such that the second side of the fourth FET die faces the third FET die; a second conductive layer arranged between the third and fourth FET dies and electrically connecting the third and fourth FET dies to each other, wherein the first and third FET dies are connected in parallel by the power electronic substrate and wherein the second and fourth FET dies are connected in parallel by the first metal clip.

Example 6 is the power semiconductor package of one of the preceding examples, wherein a drain electrode on the first side of the first FET die is connected to a source electrode on the second side of the second FET die via the first conductive layer, or wherein a source electrode on the first side of the first FET die is connected to a drain electrode on the second side of the second FET die via the first conductive layer.

Example 7 is the power semiconductor package of one of the preceding examples, wherein a first end of the first connector is attached to the first portion of the first metal clip.

Example 8 is the power semiconductor package of one of examples 1 to 6, wherein a first end of the first connector is attached to the second portion of the first metal clip.

Example 9 is the power semiconductor package of one of the preceding examples, wherein the second portion is exposed from the encapsulation body and forms an external power contact of the power semiconductor package.

Example 10 is the power semiconductor package of one of the preceding examples, further comprising: a second metal clip comprising a first portion and a second portion, wherein the first portion is arranged over the first side of the power electronic substrate and is electrically connected to a power electrode on the second side of the first FET die via the power electronic substrate and wherein the second portion is exposed from the encapsulation body, wherein the second portion of the first metal clip is exposed from a first lateral side of the encapsulation body and the second portion of the second metal clip is exposed from an opposite second lateral side of the encapsulation body.

Example 11 is the power semiconductor package of one of the preceding examples, wherein the first connector is a bond wire.

Example 12 is the power semiconductor package of one of examples 1 to 10, wherein the first connector is a third portion of the first metal clip, wherein the first, second and third portions are portions of a monolithic unit.

Example 13 is the power semiconductor package of one of the preceding examples, wherein the power electronic substrate comprises a first conductive pad and a second conductive pad, wherein the first and second FET dies are arranged over the first conductive pad, wherein a control electrode on the first side of the second FET die is electrically connected to the second conductive pad via a second connector, and wherein the first metal clip spans the second conductive pad.

Example 14 is the power semiconductor package of one of examples 1 to 12, further comprising: a third metal clip exposed from the encapsulation body, wherein a control electrode on the first side of the second FET die is electrically connected to the third metal clip such that the connection between the control electrode and the third metal clip does not comprise any conductive pad of the power electronic substrate.

Example 15 is a method for fabricating a power semiconductor package, the method comprising: providing a power electronic substrate comprising a first side and an opposite second side; arranging a first junction field-effect transistor die, first FET die, comprising a first side and an opposite second side on the power electronic substrate such that the first side of the first FET die faces away from the power electronic substrate and such that the second side of the first FET die faces the first side of the power electronic substrate; arranging a second FET die comprising a first side and an opposite second side on top of the first side of the first FET die such that the second side of the second FET die faces the first FET die; arranging a first conductive layer between the first and second FET dies and thereby electrically connecting the first and second FET dies to each other; providing a first metal clip comprising a first portion and a second portion; arranging the first portion of the first metal clip over the first side of the second FET die and electrically connecting the first portion to a first power electrode on the first side of the second FET die and arranging the second portion laterally next to the first and second FET dies; and electrically connecting a control electrode on the first side of the first FET die to the first metal clip using a first connector.

Example 16 is the method of example 15, wherein the first FET die comprises or consists of a wide-bandgap semiconductor material, in particular SiC or GaN, and the second FET die comprises or consists of Si.

Example 17 is the method of example 15 or 16, wherein the first and second FET dies are electrically connected such that the first and second FET dies form a cascode circuit.

Example 18 is the method of one of examples 15 to 17, wherein connecting the first portion of the first metal clip to the first power electrode on the first side of the second FET die comprises soldering or sintering the first portion to the first power electrode.

Example 19 is the method of one of examples 15 to 18, wherein the encapsulating comprises molding over the first and second FET dies, the first metal clip, the first conductive layer, the first connector and the first side of the power electronic substrate.

Example 20 is an apparatus comprising means for performing the method according to anyone of examples 15 to 19.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor package, comprising:
a power electronic substrate comprising a first side and an opposite second side;
a first field-effect transistor (FET) die comprising a first side and an opposite second side, the first FET die arranged on the power electronic substrate such that the first side of the first FET die faces away from the power electronic substrate and such that the second side of the first FET die faces the first side of the power electronic substrate;
a second FET die comprising a first side and an opposite second side, the second FET die arranged on top of the first side of the first FET die such that the second side of the second FET die faces the first FET die;
a first conductive layer arranged between the first and second FET dies and electrically connecting the first and second FET dies to each other;
an encapsulation body encapsulating the first and second FET dies;
a first metal clip comprising a first portion and a second portion, wherein the first portion is arranged over the first side of the second FET die and is electrically connected to a first power electrode on the first side of the second FET die, and wherein the second portion is arranged laterally next to the first and second FET dies; and
a first connector electrically connecting a control electrode on the first side of the first FET die to the first metal clip.

2. The power semiconductor package of claim 1, wherein the first FET is a depletion mode junction FET.

3. The power semiconductor package of claim 1, wherein the second FET is an enhancement mode FET.

4. The power semiconductor package of claim 1, wherein the first FET die comprises a wide-bandgap semiconductor material and the second FET die comprises Si.

5. The power semiconductor package of claim 1, wherein the second FET die has a smaller footprint than the first FET die as viewed from above the first side of the second FET die.

6. The power semiconductor package of claim 1, further comprising:
a third FET die comprising a first side and an opposite second side, the third FET die arranged on the power electronic substrate laterally next to the first FET die such that the first side of the third FET die faces away from the power electronic substrate and such that the second side of the third FET die faces the first side of the power electronic substrate;
a fourth FET die comprising a first side and an opposite second side, the fourth FET die arranged on top of the first side of the third FET die such that the second side of the fourth FET die faces the third FET die;
a second conductive layer arranged between the third and fourth FET dies and electrically connecting the third and fourth FET dies to each other,
wherein the first and third FET dies are connected in parallel by the power electronic substrate, and
wherein the second and fourth FET dies are connected in parallel by the first metal clip.

7. The power semiconductor package of claim 1, wherein a drain electrode on the first side of the first FET die is connected to a source electrode on the second side of the second FET die via the first conductive layer, or a source electrode on the first side of the first FET die is connected to a drain electrode on the second side of the second FET die via the first conductive layer.

8. The power semiconductor package of claim 1, wherein a first end of the first connector is attached to the first portion of the first metal clip.

9. The power semiconductor package of claim 1, wherein a first end of the first connector is attached to the second portion of the first metal clip.

10. The power semiconductor package of claim 1, wherein the second portion is exposed from the encapsulation body and forms an external power contact of the power semiconductor package.

11. The power semiconductor package of claim 1, further comprising:
a second metal clip comprising a first portion and a second portion, the first portion being arranged over the first side of the power electronic substrate and electrically connected to a power electrode on the second side of the first FET die via the power electronic substrate, and the second portion being exposed from the encapsulation body,
wherein the second portion of the first metal clip is exposed from a first lateral side of the encapsulation body and the second portion of the second metal clip is exposed from an opposite second lateral side of the encapsulation body.

12. The power semiconductor package of claim 1, wherein the first connector is a bond wire.

13. The power semiconductor package of claim 1, wherein the first connector is a third portion of the first metal clip, and wherein the first, second and third portions are portions of a monolithic unit.

14. The power semiconductor package of claim 1, wherein the power electronic substrate comprises a first conductive pad and a second conductive pad, wherein the first and second FET dies are arranged over the first conductive pad, wherein a control electrode on the first side of the second FET die is electrically connected to the second conductive pad via a second connector, and wherein the first metal clip spans the second conductive pad.

15. The power semiconductor package of claim 1, further comprising:
a third metal clip exposed from the encapsulation body,
wherein a control electrode on the first side of the second FET die is electrically connected to the third metal clip such that the connection between the control electrode and the third metal clip does not comprise any conductive pad of the power electronic substrate.

16. A method for fabricating a power semiconductor package, the method comprising:
providing a power electronic substrate comprising a first side and an opposite second side;
arranging a first junction field-effect transistor (FET) die comprising a first side and an opposite second side on the power electronic substrate such that the first side of the first FET die faces away from the power electronic substrate and such that the second side of the first FET die faces the first side of the power electronic substrate;
arranging a second FET die comprising a first side and an opposite second side on top of the first side of the first FET die such that the second side of the second FET die faces the first FET die;
arranging a first conductive layer between the first and second FET dies and thereby electrically connecting the first and second FET dies to each other;
providing a first metal clip comprising a first portion and a second portion;
arranging the first portion of the first metal clip over the first side of the second FET die and electrically connecting the first portion to a first power electrode on the first side of the second FET die;
arranging the second portion of the first metal clip laterally next to the first and second FET dies; and
electrically connecting a control electrode on the first side of the first FET die to the first metal clip using a first connector.

17. The method of claim 16, wherein the first FET die comprises a wide-bandgap semiconductor material and the second FET die comprises Si.

18. The method of claim 16, wherein the first and second FET dies are electrically connected such that the first and second FET dies form a cascode circuit.

19. The method of claim 16, wherein connecting the first portion of the first metal clip to the first power electrode on the first side of the second FET die comprises soldering or sintering the first portion to the first power electrode.

20. The method of claim 16, further comprising:
encapsulating the first and second FET dies with an encapsulation body,
wherein the encapsulating comprises molding over the first and second FET dies, the first metal clip, the first conductive layer, the first connector, and the first side of the power electronic substrate.
